(19) United States
(12) Patent Application Publication
(10) Pub. No.: US 2023/0107916 A1
(43) Pub. Date: Apr. 6, 2023

(54) HIGH FREQUENCY CIRCUIT

(71) Applicant: Sumitomo Electric Industries, Ltd., Osaka (JP)

(72) Inventor: Takashi SUMIYOSHI, Osaka-shi (JP)

(73) Assignee: Sumitomo Electric Industries, Ltd., Osaka (JP)

(21) Appl. No.: 17/859,141

(22) Filed: Jul. 7, 2022

(30) Foreign Application Priority Data
Oct. 4, 2021 (JP) 2021-163306

(51) Int. Cl. H03F 3/195; H03F 1/56; H03F 3/60

(52) U.S. Cl. CPC H03F 3/195; H03F 1/565; H03F 3/601

(57) ABSTRACT

A high frequency circuit includes a transistor amplifying a high frequency signal, and having an input electrode and an output electrode, a line that is connected to any one of the input electrode and the output electrode, and transmits a high frequency signal or an amplified high frequency signal, a bias terminal to which a bias voltage is supplied, a bias circuit that has a first end connected to a first node and a second end connected to the bias terminal, and suppresses a high frequency signal having a frequency within an operating frequency band of the transistor from passing from the first node to the bias terminal, and a resonance circuit that is connected between a reference potential and a second node provided between the bias terminal and the bias circuit, and minimizes an impedance between the second node and the reference potential at a resonance frequency.

### CROSS REFERENCE TO RELATED APPLICATIONS

This application claims priority based on Japanese Patent Application No. 2021-163306 filed on Oct. 4, 2021, and the entire contents of the Japanese patent applications are incorporated herein by reference.

### FIELD

The present disclosure relates to a high frequency circuit.

### BACKGROUND

It is known that an first end of an open stub is connected to a main line through which a high frequency signal is transmitted in a high frequency circuit, the transmission line is brought close to the open stub, and both ends of the transmission line are grounded via a resistance (for example, Patent Document 1: Japanese Laid-open Patent Publication No. 09-284051). It is known to provide a capacitor shunt-connected to a choke coil of a bias circuit that supplies a bias voltage to a transistor, and provide a parallel resonance circuit using the choke coil and the capacitor (for example, Patent Document 2: Japanese Laid-open Patent Publication No. 2000-183773).

### SUMMARY

A high frequency circuit according to the present disclosure includes: a transistor amplifying a high frequency signal, and having an input electrode that inputs the high frequency signal and an output electrode that outputs an amplified high frequency signal; a line that is connected to any one of the input electrode and the output electrode, and transmits the high frequency signal or the amplified high frequency signal; a bias terminal to which a bias voltage applied to the any one of the input electrode and the output electrode of the transistor is supplied; a bias circuit that has a first end connected to a first node in the line and a second end connected to the bias terminal, and suppresses a high frequency signal having a frequency within an operating frequency band of the transistor among the high frequency signal or the amplified high frequency signal from passing from the first node to the bias terminal; and a resonance circuit that is connected between a reference potential and a second node provided between the bias terminal and the bias circuit, and minimizes an impedance between the second node and the reference potential at a resonance frequency.

### BRIEF DESCRIPTION OF DRAWINGS

FIG. 1 is a circuit diagram illustrating a high frequency circuit according to a first embodiment.

FIG. 2 is a plan view illustrating a bias circuit and a resonance circuit according to the first embodiment.

FIG. 3 is a cross-sectional view taken along line A-A of FIG. 2.

FIG. 4 is a circuit diagram illustrating a high frequency circuit according to a first comparative example.

FIG. 5 is a circuit diagram illustrating a high frequency circuit according to a first variation of the first embodiment.

FIG. 6 is a circuit diagram illustrating a high frequency circuit according to a second embodiment.

FIG. 7 is a diagram illustrating a parameter S21 with respect to a frequency in a circuit A.

FIG. 8 is a diagram illustrating a parameter S21 with respect to a frequency in a circuit B.

### DETAILED DESCRIPTION OF EMBODIMENTS

In Patent Documents 1 and 2, the operation of the high frequency circuit can be stabilized. However, if a stabilizing circuit that stabilizes the operation of the high frequency circuit is directly connected to a line on which the high frequency signal is transmitted, the characteristics of the high frequency circuit are affected and the characteristics are deteriorated.

The present disclosure has been made in view of the above problems, and an object of the present disclosure is to stabilize the operation and suppress the deterioration of the characteristics.

### Description of Embodiments of the Present Disclosure

First, the contents of the embodiments of this disclosure are listed and explained.

(1) A high frequency circuit according to the present disclosure includes: a transistor amplifying a high frequency signal, and having an input electrode that inputs the high frequency signal and an output electrode that outputs an amplified high frequency signal; a line that is connected to any one of the input electrode and the output electrode, and transmits the high frequency signal or the amplified high frequency signal; a bias terminal to which a bias voltage applied to the any one of the input electrode and the output electrode of the transistor is supplied; a bias circuit that has a first end connected to a first node in the line and a second end connected to the bias terminal, and suppresses a high frequency signal having a frequency within an operating frequency band of the transistor among the high frequency signal or the amplified high frequency signal from passing from the first node to the bias terminal; and a resonance circuit that is connected between a reference potential and a second node provided between the bias terminal and the bias circuit, and minimizes an impedance between the second node and the reference potential at a resonance frequency. The resonance circuit between the bias terminal and the bias circuit can suppress the deterioration of the characteristics and stabilize the operation.

(2) The high frequency circuit further may include an input terminal that inputs the high frequency signal, and a matching circuit connected between the input terminal and the input electrode. The matching circuit may match an impedance when the matching circuit is viewed from the input terminal with an impedance when the input electrode is viewed from the matching circuit, and the line may connect the matching circuit to the input electrode.

(3) The high frequency circuit further may include an output terminal that outputs the amplified high frequency signal, and a matching circuit connected between the output electrode and the output terminal. The matching circuit may match an impedance when the matching circuit is viewed from the output electrode with an impedance when the output terminal is viewed from the matching circuit, and the line may connect the output electrode to the matching circuit.

(4) At the resonance frequency of the resonance circuit, a stability coefficient of the high frequency circuit when the resonance circuit is not provided may be less than 1.

(5) The resonance frequency of the resonance circuit may be lower than an operating frequency band of the high frequency circuit.

(6) The input electrode may be a gate of the transistor and the output electrode may be a drain of the transistor.

(7) The resonance circuit may include a first inductor and a first capacitor connected in series between the second node and the reference potential.

(8) The bias circuit may include a second inductor having a first end connected to the first node and a second end connected to the second node, and a second capacitor having a first end connected to the second node and a second end connected to the reference potential.

### Details of Embodiments of the Present Disclosure

Specific examples of a high frequency circuit in accordance with embodiments of the present disclosure are described below with reference to the drawings. The present disclosure is not limited to these examples, but is indicated by the claims, which are intended to include all modifications within the meaning and scope of the claims.

### FIRST EMBODIMENT

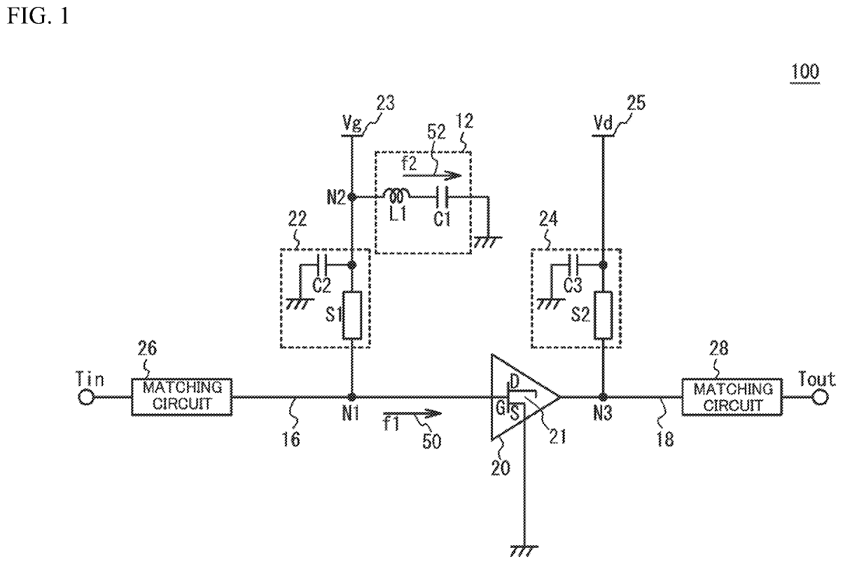

In a first embodiment, a high frequency power amplifier used as a base station for mobile communication as a high frequency circuit will be described as an example. FIG. 1 is a circuit diagram illustrating the high frequency circuit according to the first embodiment. As illustrated in FIG. 1, a high frequency circuit 100 includes a resonance circuit 12, an amplifier 20, bias circuits 22 and 24, and matching circuits 26 and 28. The amplifier 20 includes a transistor 21. The transistor 21 is a FET (Field Effect Transistor) such as, for example, a GaN HEMT (Gallium Nitride High Electron Mobility Transistor). A center frequency in an operating frequency band of the high frequency circuit 100 is, for example, 0.5 GHz to 10 GHz.

An input terminal Tin is connected to a gate G (an input electrode that inputs the high frequency signal) of the transistor 21 via the matching circuit 26, and a drain D (an output electrode that outputs an amplified high frequency signal) of the transistor 21 is connected to an output terminal Tout via the matching circuit 28. A source S of the transistor 21 is connected to a ground potential (reference potential). The transistor 21 amplifies a high frequency signal 50 input to the input terminal Tin and outputs the amplified high frequency signal 50 to the output terminal Tout. A frequency f1 of the high frequency signal 50 amplified by the amplifier 20 is, for example, a center frequency in an operating frequency band of the high frequency circuit 100. The matching circuit 26 matches an input impedance when the input terminal Tin is viewed from an external circuit at the frequency f1 with an input impedance when the gate G is viewed from the matching circuit 26. That is, the matching circuit 26 matches the impedance when the matching circuit 26 is viewed from the input terminal Tin with the impedance when the gate G is seen from the matching circuit 26. The matching circuit 28 matches an output impedance when the matching circuit 28 is viewed from the drain D at the frequency f1 with an output impedance when the external circuit is viewed from the output terminal Tout. That is, the matching circuit 28 matches the impedance when the matching circuit 28 is viewed from the drain D with the impedance when the output terminal Tout is viewed from the matching circuit 28.

The bias circuit 22 is connected to a node N1 in a line 16 connected between the matching circuit 26 and the gate G. The bias circuit 22 includes a transmission line S1 and a capacitor C2. A first end of the transmission line S1 is connected to the node N1, and a second end of the transmission line S1 is connected to a bias terminal 23. A first end of the capacitor C2 is connected to a node N2 between the transmission line S1 and the bias terminal 23, and a second end of the capacitor C2 is connected to the reference potential such as ground. When the wavelength at the frequency f1 is λ, the length of the transmission line S1 is, for example, λ/4. The bias circuit 22 applies a bias voltage Vg supplied to the bias terminal 23 to the gate G via the line 16 and suppresses the high frequency signal 50 from passing from the node N1 to the bias terminal 23.

The bias circuit 24 is connected to a node N3 in a line 18 connected between the drain D and the matching circuit 28. The bias circuit 24 includes a transmission line S2 and a capacitor C3. A first end of the transmission line S2 is connected to the node N3, and the second end of the transmission line S2 is connected to a bias terminal 25. A first end of the capacitor C3 is connected to a node between the transmission line S2 and the bias terminal 25, and a second end of the capacitor C3 is connected to the ground. The length of the transmission line S2 is, for example, λ4. The bias circuit 24 applies a bias voltage Vd supplied to the bias terminal 25 to the drain D via the line 18 and suppresses the high frequency signal 50 from passing from the node N3 to the bias terminal 25.

The resonance circuit 12 is a series resonance circuit including an inductor L1 and a capacitor C1. The inductor L1 and the capacitor C1 are connected in series between the reference potential such as ground, and the node N2 provided between the bias circuit 22 and the bias terminal 23. An impedance between the node N2 and the reference potential is minimized at a resonance frequency fr of the resonance circuit 12. The resonance frequency fr is, for example, around a frequency f2 at which the high frequency circuit 100 is likely to oscillate (i.e., the high frequency circuit 100 is likely to become unstable) when the resonance circuit 12 is not provided. A high frequency signal 52 having a frequency f2 passes through the bias circuit 22.

A stability coefficient K of the high frequency circuit 100 is given by the following formula 1.

$$K = \frac{1 - {\vert {S}_{11} \vert}^{2} - {\vert {S}_{22} \vert}^{2} + {\vert D \vert}^{2}}{2 \vert {S}_{12} {S}_{21} \vert} \qquad ( Formula 1 )$$

Here, “D=S11×S22−S12×S21” is satisfied, and S11, S22, S21 and S12 are S-parameters when the input terminal Tin and the output terminal Tout are set to a port 1 and a port 2, respectively.

When the stability coefficient K is 1 or less, the high frequency circuit 100 becomes unstable and easily oscillates. The high frequency circuit 100 is designed using the matching circuits 26 and 28 so that the stability coefficient K is larger than 1 in an operating frequency band of the high frequency circuit 100. However, when the stability coefficient K is 1 or less at a frequency other than the operating frequency band, the high frequency circuit 100 is likely to oscillate. Since the high frequency signal 52 having the frequency f2 near the resonance frequency fr flows from the transmission line 16 to the ground via the bias circuit 22 and the resonance circuit 12, the parameter S21 at the frequency f2 decreases. According to formula 1, as the parameter S21 decreases, the stability coefficient K increases. Therefore, the stability coefficient K near the frequency f2 can be increased. The high frequency signal 50 having the frequency f1 is hard to pass through the bias circuit 22. Therefore, the high frequency signal 50 does not flow to the reference potential. Therefore, the resonance circuit 12 has almost no effect on the line 16 at the frequency f1, and the gain at the frequency f1 of the high frequency circuit 100 hardly changes depending on the presence or absence of the resonance circuit 12.

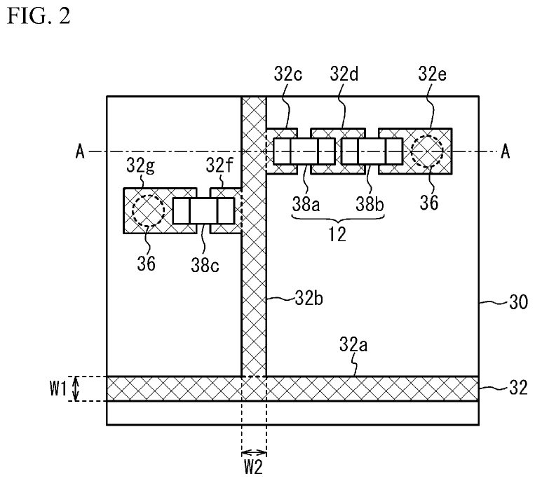

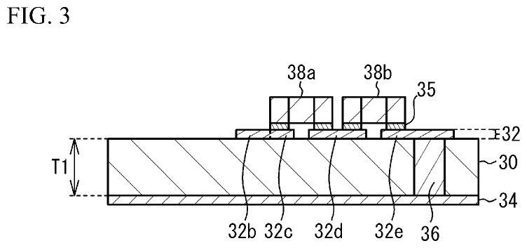

FIG. 2 is a plan view illustrating the bias circuit and the resonance circuit according to the first embodiment. FIG. 3 is a cross-sectional view taken along line A-A of FIG. 2. As illustrated in FIGS. 2 and 3, a metal layer 32 is provided on an upper surface of a dielectric substrate 30, and a metal layer 34 is provided on a lower surface of the dielectric substrate 30. The dielectric substrate 30 is a dielectric substrate made of a resin or ceramic such as FR-4 (Flame Retardant Type 4). The metal layers 32 and 34 are, for example, a copper layer or a gold layer. The metal layer 34 is provided on the entire lower surface of the dielectric substrate 30, and the reference potential such as the ground potential is supplied to the metal layer 34. The metal layer 32 forms patterns 32a to 32g.

The pattern 32a is a signal line of the line 16. The pattern 32a and the metal layer 32 form a microstrip line. A first end of a pattern 32b is connected to the pattern 32a, and a second end of the pattern 32b is the bias terminal 23. The pattern 32b and the metal layer 32 form a microstrip line. A part of the pattern 32b and the metal layer 34 form the transmission line S1. The widths of the patterns 32a and 32b are W1 and W2. The widths W1, W2 and the thickness T1 are designed so that the characteristic impedances of the line 16 and the transmission line S1 become desired values at the frequency f1.

A pattern 32c is connected between the transmission line S1 in the pattern 32b and the bias terminal 23. A pattern 32d is provided away from the pattern 32c, and a pattern 32e is provided away from the pattern 32d. Both ends of an electronic component 38a are bonded on the patterns 32c and 32d using a bonding material 35, respectively. Both ends of an electronic component 38b are bonded on the patterns 32d and 32e using the bonding material 35, respectively. The pattern 32e is electrically connected to the metal layer 34 by a through electrode 36 penetrating the dielectric substrate 30 and is short-circuited. The electronic component 38a is a coil component and corresponds to the inductor L1. The electronic component 38b is a capacitor component and corresponds to the capacitor C1. The resonance circuit 12 is formed by the electronic components 38a and 38b.

A pattern 32f is connected between the transmission line S1 in the pattern 32b and the bias terminal 23. A pattern 32g is provided away from the pattern 32f. Both ends of an electronic component 38c are bonded on the patterns 32f and 32g using the bonding material 35, respectively. The pattern 32g is electrically connected to the metal layer 34 by the through electrode 36 penetrating the dielectric substrate 30 and is short-circuited. The electronic component 38c is a capacitor component and corresponds to the capacitor C2.

Although the electronic components 38a to 38c are used as the inductor L1, the capacitor C1 and the resistor R1 as an example, the inductor L1 may be a line pattern formed by the metal layer 32. The capacitors C1 and C2 may be MIM (Metal Insulator Metal) capacitors provided on the dielectric substrate 30.

### COMPARATIVE EXAMPLE

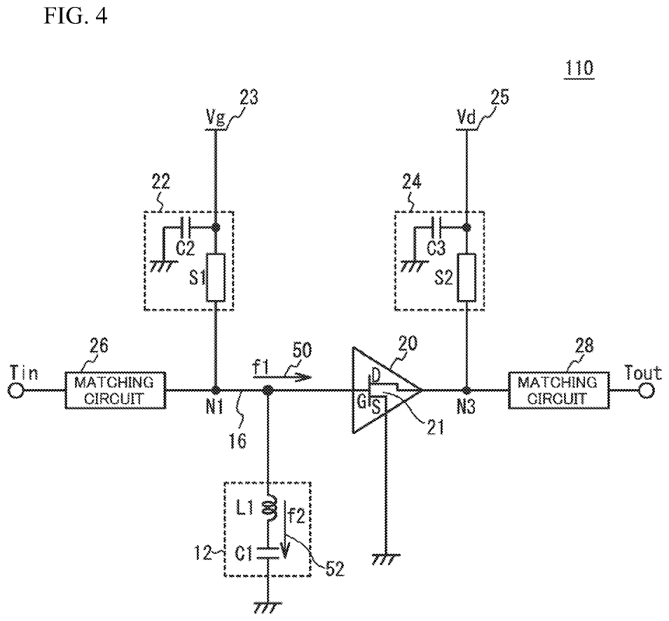

FIG. 4 is a circuit diagram illustrating a high frequency circuit according to a first comparative example. As illustrated in FIG. 4, in a high frequency circuit 110 in the first comparative example, the resonance circuit 12 is shunt-connected to the line between the matching circuit 26 and the gate G. In the first comparative example, the stability coefficient K of the high frequency circuit 110 at the frequency f2 can be increased by setting the resonance frequency fr of the resonance circuit 12 to be in the vicinity of the frequency f2 of the high frequency signal 52, as in the first embodiment. On the other hand, the operating frequency band of the high frequency circuit 110 is different from the resonance frequency of the resonance circuit 12. Therefore, the impedance of the resonance circuit 12 becomes high in the vicinity of the frequency f1 of the high frequency signal 50. Therefore, the decrease in the gain of the high frequency circuit 110 at the frequency f1 is suppressed.

However, at the frequency f1, the impedance of the resonance circuit 12 is high but not infinite. Therefore, a part of the high frequency signal 50 leaks to the reference potential via the resonance circuit 12. This increases the loss at the frequency f1. Further, the inductor L1 and the capacitor C1 in the resonance circuit 12 affect the line 16. For example, the resonance circuit 12 affects the impedance matching between the input terminal Tin and the gate G. Thereby, the impedance matching by the matching circuit 26 changes from an optimum state, and the high frequency characteristic of the high frequency circuit 110 deteriorates.

According to the first embodiment, the transmission line 16 for transmitting the high frequency signal 50 is connected to the gate G (input electrode that inputs the high frequency signal) of the transistor 21, as illustrated in FIG. 1. The bias voltage applied to the gate G is supplied to the bias terminal 23. The bias circuit 22 has a first end connected to the node N1 (first node) in the line 16 and a second end connected to the bias terminal 23. A part of the high frequency signal 52 having the frequency f2 different from the frequency f1 passes through the bias circuit 22. The resonance circuit 12 is connected between the node N2 (second node) and the ground (reference potential), and minimizes the impedance between the node N2 and the ground at the resonance frequency fr. Thereby, the high frequency signal 52 having the frequency f2 among the high frequency signals that have passed through the bias circuit 22 flows to the ground via the resonance circuit 12. Therefore, the operation of the high frequency circuit 100 can be stabilized at the frequency f2. The bias circuit 22 suppresses the high frequency signal 50 having a frequency within the operating frequency band of the transistor among the high frequency signals input to the input terminal Tin from passing from the node N1 to the bias terminal 23. Thereby, the high frequency signal 50 having the frequency f1 can be suppressed from flowing to the ground, and the decrease in the gain at the frequency f1 can be suppressed. In addition, since the resonance circuit 12 is not visible from the high frequency signal 50 transmitted on the line 16, the resonance circuit 12 can be suppressed from affecting the high frequency signal 50.

The line 16 connects the gate G to the matching circuit 26 that matches the input impedance of the input terminal Tin with the input impedance of the gate G. The bias circuit 22 is connected to the node N1 in the line 16. When the resonance circuit 12 is directly connected to the line 16 as in the first comparative example, the resonance circuit 12 causes the impedance matching by the matching circuit 26 to deviate from the optimum value. Therefore, it is preferable to connect the resonance circuit 12 between the node N2 and the ground as in the first embodiment.

The resonance circuit 12 includes the inductor L1 (first inductor) and the capacitor C1 (first capacitor) connected in series between the node N2 and the ground. Thereby, the resonance circuit 12 is short-circuited at the resonance frequency fr, and the high frequency signal 52 having the frequency f2 in the vicinity of the resonance frequency fr can be passed to the ground to increase the stability coefficient K at the frequency f2. A connection order of the inductor L1 and the capacitor C1 may be reversed from that of the first embodiment.

The bias circuit 22 includes the transmission line S1 (second inductor) having a first end connected to the node N1 and a second end connected to the node N2, and the capacitor C2 (second capacitor) having a first end connected to the node N2 and a second end connected to a reference potential. Thereby, the bias circuit 22 that suppresses the passage of the high frequency signal 50 can be formed. The second inductor may function as a choke coil. For example, when the wavelength of the frequency f1 is λ, the electrical length of the transmission line S1 is λ/4, which is larger than λ/8 and smaller than 3λ/8. Thereby, the transmission line S1 functions as the choke coil.

### FIRST VARIATION OF FIRST EMBODIMENT

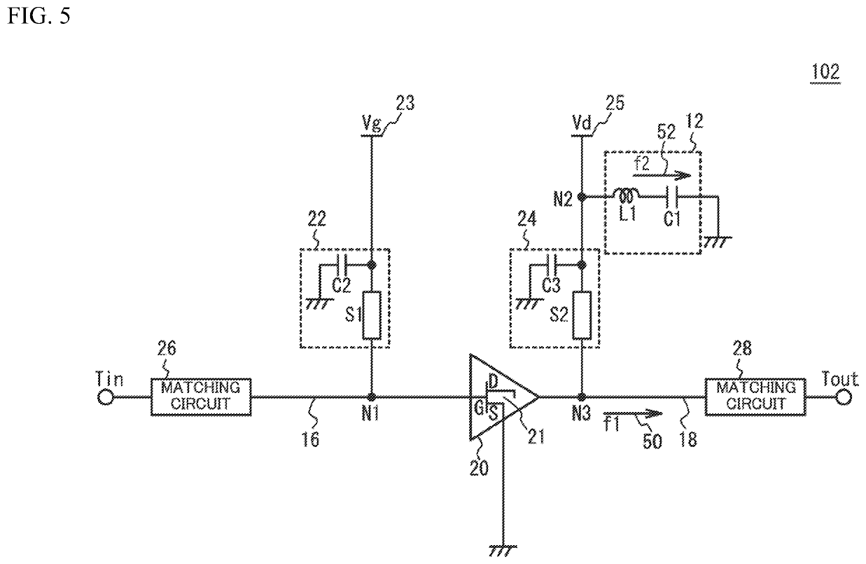

FIG. 5 is a circuit diagram illustrating a high frequency circuit according to a first variation of the first embodiment. As illustrated in FIG. 5, in a high frequency circuit 102 of the first variation of the first embodiment, the line 18 connects the drain D to the matching circuit 28 that matches the output impedance of the drain D with the output impedance of the output terminal Tout, and the high frequency signal amplified by the transistor 21 is transmitted through the line 18. The bias circuit 24 is connected to the node N3 in the line 18, and suppresses the high frequency signal having a frequency within the operating frequency band of the transistor 21 among the amplified high frequency signals from passing from the node N3 to the bias terminal 25. The resonance circuit 12 is provided between the ground, and the node N2 provided between the bias circuit 24 and the bias terminal 25. Other configurations are the same as those in the first embodiment, and the description thereof will be omitted. As in the first variation of the first embodiment, the resonance circuit 12 may be provided between the bias circuit 24 and the bias terminal 25 for supplying the drain bias voltage Vd.

When the transistor 21 is the amplifier 20, a high frequency signal having a large power is output to the drain D. Therefore, in the first variation of the first embodiment, each electronic component (electronic components 38a to 38c in FIGS. 2 and 3) in the resonance circuit 12 is an expensive component having a high withstand voltage. Therefore, the resonance circuit 12 is preferably provided between the bias circuit 22 and the bias terminal 23 as in the first embodiment. When the transistor 21 functions as a multiplier or a mixer, the resonance circuit 12 may be provided between the bias circuit 24 and the bias terminal 25, as in the first variation of the first embodiment.

### SECOND EMBODIMENT

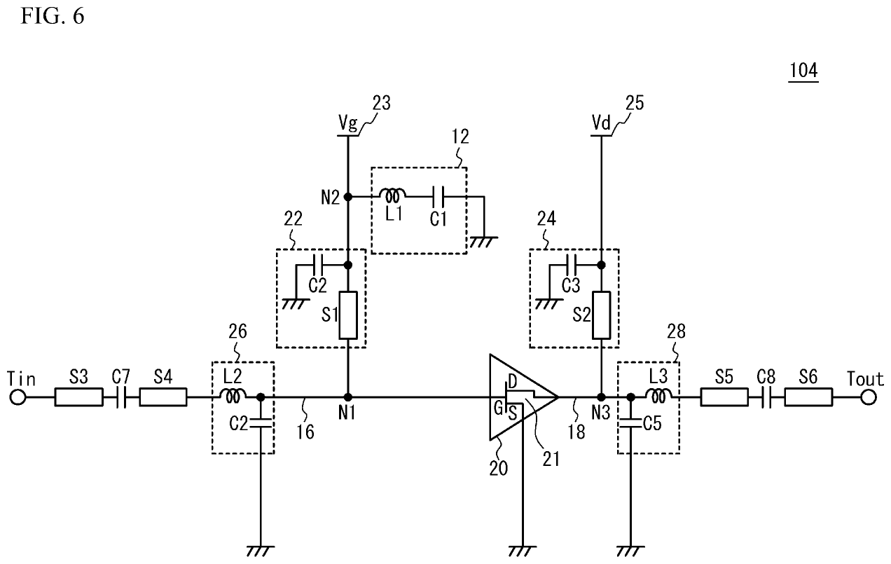

A second embodiment is a specific example of the first embodiment. FIG. 6 is a circuit diagram illustrating a high frequency circuit according to the second embodiment. As illustrated in FIG. 6, in a high frequency circuit 104, a transmission line S3, a capacitor C7, and a transmission line S4 are connected between the input terminal Tin and the matching circuit 26. A transmission line S5, a capacitor C8, and a transmission line S6 are connected between the matching circuit 28 and the output terminal Tout. The transmission lines S3 to S6 are lines that propagate the high frequency signal. The capacitors C7 and C8 are DC cut capacitors that pass the high frequency signal and cut a DC (Direct Current) component.

The matching circuit 26 includes an inductor L2 connected in series and a capacitor C2 connected in shunt. The matching circuit 28 includes an inductor L3 connected in series and a capacitor C5 connected in shunt. The matching circuits 26 and 28 are LCL-T type circuits, CLC-π type circuits or the like, and can be appropriately formed by using inductors and capacitors. The matching circuits 26 and 28 may be formed by using distributed constant circuits. Other configurations are the same as those in FIG. 1 of the first embodiment, and the description thereof will be omitted.

### SIMULATION

The simulation of the high frequency circuit 104 in the second embodiment was performed. The simulation was performed for a circuit A provided without the resonance circuit 12 and a circuit B with the resonance circuit 12. The simulation conditions are as follows.

Center frequency of operating frequency band: 4.8 GHz

### Transistor 21: GaN HEMT

### R1:50Ω

L1 (nH), C1 (pF): The values of the elements were selected so that the resonance frequency of the series resonance circuit composed of L1 and C1 was included in the frequency band where the stability coefficient K<1 was satisfied in the circuit A without the resonance circuit 12.

Table 1 illustrates fo, K@fo, S21@fo, and S21@fc in the circuits A and B. The frequency fo is a frequency having a minimum stability coefficient at 1.5 GHz to 7 GHz, and K@fo and S21@fo are the stability coefficient K and the parameter S21 at the frequency fo. S21@fc is the parameter S21 at the center frequency fc of the operating frequency band.

TABLE 1

| | RESONANCE | fo | | S21@fo | S21@fc |
|---|---|---|---|---|---|
| CIRCUIT | CIRCUIT | [GHz] | K@fo | [dB] | [dB] |
| A | ABSENCE | 1.71 | 0.757 | 15.17 | 11.45 |
| B | PRESENCE | 1.64 | 0.984 | 12.92 | 11.45 |

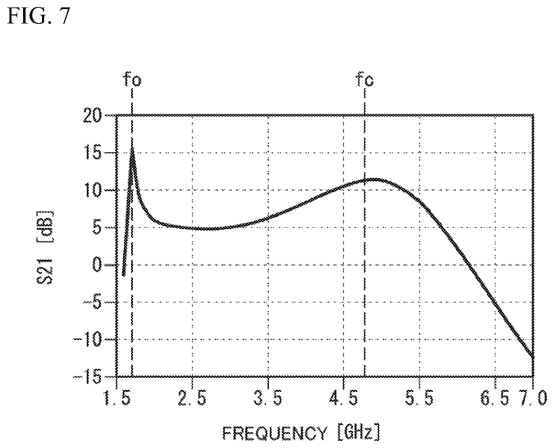

FIG. 7 is a diagram illustrating the parameter S21 with respect to the frequency in the circuit A. As illustrated in FIG. 7 and Table 1, S21@fc at the center frequency fc is 11.45 dB. S21@fo at the frequency fo=1.71 GHz is 15.17 dB. Since the parameter S21 is large, the stability coefficient K becomes small as in formula 1. K@fo at the frequency fo is 0.757, and the operation of the high frequency circuit becomes unstable.

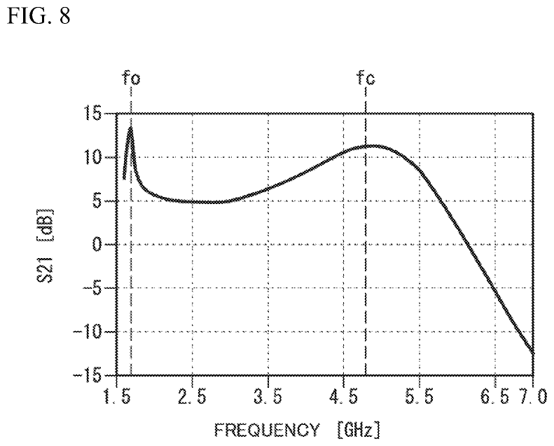

FIG. 8 is a diagram illustrating the parameter S21 with respect to the frequency in the circuit B. As illustrated in FIG. 8 and Table 1, S21@fc at the center frequency fc is 11.45 dB, and is the same as S21@fc of the circuit A. S21@fo at the frequency fo=1.64 GHz is 12.92 dB, and is smaller than S21@fo of circuit A. Thereby, K@fo of the circuit B becomes larger than that of the circuit A. K@fo at the frequency fo is 0.984, and hence the operation of the high frequency circuit is more stable in the circuit B than in the circuit A.

In this way, the resonance frequency of the resonance circuit 12 is set in the vicinity of the frequency fo where the stability coefficient K becomes smaller as the parameter S21 representing the gain increases in the circuit A. Thereby, S21@fo at the frequency fo becomes small, and the stability coefficient K@fo at the frequency fo becomes large. Therefore, the operation of the high frequency circuit 104 is stabilized. Further, the parameter S21 representing the gain at the center frequency fc hardly deteriorates even if the resonance circuit 12 is provided.

As in the circuit A, at the resonance frequency of the resonance circuit 12, the stability coefficient K of the high frequency circuit when the resonance circuit 12 is not provided is less than 1. When the resonance circuit 12 is provided as in the circuit B in such a high frequency circuit, the stability coefficient K can be increased. When the stability coefficient K at the resonance frequency of the resonance circuit 12 in the case where the resonance circuit 12 is not provided in the high frequency circuit is 0.95 or less or 0.9 or less, it is preferable to provide the resonance circuit 12.

As in the circuit A, the gain is likely to be large and the stability coefficient K is likely to be small at frequencies lower than the operating frequency band of the high frequency circuit. Therefore, it is preferable that the resonance frequency of the resonance circuit 12 is lower than the frequencies in the operating frequency band of the high frequency circuit. The resonance frequency of the resonance circuit 12 is more preferably ½ or less of the frequencies in the operating frequency band, and further preferably ⅓ or less of the frequencies in the operating frequency band.

In the first and the second embodiments, an example of a FET such as a GaN HEMT has been described as the transistor 21, but the transistor 21 may be a bipolar transistor. In the high frequency circuit in which the transistor 21 is the FET, the input electrode is the gate, and the output electrode is the drain, the stability coefficient K is likely to be less than 0.9 at a frequency lower than the operating band unless the resonance circuit 12 is provided. Therefore, it is preferable to provide the resonance circuit 12 in order to set the stability coefficient K to 0.9 or more.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A high frequency circuit comprising:
a transistor amplifying a high frequency signal, and having an input electrode that inputs the high frequency signal and an output electrode that outputs an amplified high frequency signal;
a line that is connected to any one of the input electrode and the output electrode, and transmits the high frequency signal or the amplified high frequency signal;
a bias terminal to which a bias voltage applied to the any one of the input electrode and the output electrode of the transistor is supplied;
a bias circuit that has a first end connected to a first node in the line and a second end connected to the bias terminal, and suppresses a high frequency signal having a frequency within an operating frequency band of the transistor among the high frequency signal or the amplified high frequency signal from passing from the first node to the bias terminal; and
a resonance circuit that is connected between a reference potential and a second node provided between the bias terminal and the bias circuit, and minimizes an impedance between the second node and the reference potential at a resonance frequency.

2. The high frequency circuit as claimed in claim 1, further comprising:
an input terminal that inputs the high frequency signal; and
a matching circuit connected between the input terminal and the input electrode;
wherein the matching circuit matches an impedance when the matching circuit is viewed from the input terminal with an impedance when the input electrode is viewed from the matching circuit, and
the line connects the matching circuit to the input electrode.

3. The high frequency circuit as claimed in claim 1, further comprising:
an output terminal that outputs the amplified high frequency signal; and
a matching circuit connected between the output electrode and the output terminal;
wherein the matching circuit matches an impedance when the matching circuit is viewed from the output electrode with an impedance when the output terminal is viewed from the matching circuit, and
the line connects the output electrode to the matching circuit.

4. The high frequency circuit as claimed in claim 1, wherein
at the resonance frequency of the resonance circuit, a stability coefficient of the high frequency circuit when the resonance circuit is not provided is less than 1.

5. The high frequency circuit as claimed in claim 1, wherein
the resonance frequency of the resonance circuit is lower than an operating frequency band of the high frequency circuit.

6. The high frequency circuit as claimed in claim 1, wherein
the input electrode is a gate of the transistor and the output electrode is a drain of the transistor.

7. The high frequency circuit as claimed in claim 1, wherein
the resonance circuit includes a first inductor and a first capacitor connected in series between the second node and the reference potential.

8. The high frequency circuit as claimed in claim 1, wherein
the bias circuit includes a second inductor having a first end connected to the first node and a second end connected to the second node, and
a second capacitor having a first end connected to the second node and a second end connected to the reference potential.
